(19) United States
(12) Patent Application Publication
(10) Pub. No.: US 2025/0279265 A1
(43) Pub. Date: Sep. 4, 2025

(54) SMALL CELL REACTORS WITH SHARED FORELINE AND PRESSURE CONDUIT

(71) Applicant: Applied Materials, Inc., Santa Clara, CA (US)

(72) Inventors: Vishwas BASAVARAJAIAH SOMASHEKAR, Bangalore (IN); Akshay DHANAKSHIRUR, Hubli (IN); Kaushik ALAYAVALLI, Sunnyvale, CA (US); Nitin KADAM, Bengaluru (IN); Vishwas Kumar PANDEY, Madhya Pradesh (IN)

(21) Appl. No.: 18/592,180

(22) Filed: Feb. 29, 2024

(51) Int. Cl. H01J 37/32; C23C 16/44; C23C 16/455

(52) U.S. Cl. CPC H01J 37/32834; C23C 16/4412; C23C 16/45591; H01J 37/32899; H01J 2237/332

(57) ABSTRACT

In one embodiment, a processing system for semiconductor manufacturing, includes a chamber housing, a first process chamber, a second process chamber and a foreline disposed in the chamber housing and between the first process chamber and the second process chamber. The first and second process chambers are in the chamber housing and each includes a pump ring and a liner. The pump ring includes a port and baffle. The pump rings and liners each partially define a first and second process volume respectively. The foreline includes a first exhaust chamber fluidly coupled to the first process volume and a second exhaust chamber fluidly coupled to the second process volume.

### BACKGROUND

### Field

Embodiments of the present invention generally relate to components, apparatus, and systems for semiconductor manufacturing. More specifically, the present technology relates to processing chamber components and other semiconductor processing equipment.

### Description of the Related Art

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies between substrate processing chambers may impact the formation or removal of material between similar substrates.

Thus, there is a need for improved systems and methods that can be used to produce high quality devices and structures with enhanced throughput and increased accuracy. These and other needs are addressed by the present technology.

### SUMMARY

To be completed Embodiments herein include a processing system for semiconductor manufacturing. In one embodiment, a processing system for semiconductor manufacturing is provided. The processing system includes a chamber housing, a first process chamber, a second process chamber and a foreline disposed in the chamber housing and between the first process chamber and the second process chamber. The first process chamber is in the chamber housing and includes a first pump ring and a first liner. The first pump ring includes a first port and first baffle. The first pump ring and first liner partially define a first process volume. The second process chamber is in the chamber housing and includes a second pump ring and a second liner. The second pump ring includes a second port and second baffle. The second pump ring and second liner partially define a second process volume. The foreline is in the chamber housing and between the first process chamber and the second process chamber. The foreline includes a first exhaust chamber fluidly coupled to the first process volume and a second exhaust chamber fluidly coupled to the second process volume.

In another embodiment, a processing system for semiconductor manufacturing is provided. The processing system includes a chamber housing, a first process chamber, a second process chamber, a pressure sensor, and a foreline disposed in the chamber housing and between the first process chamber and the second process chamber. The first process chamber is disposed in the chamber housing and includes a first pump ring and a first liner. The first pump ring includes a first port, a first baffle, and a first pressure conduit disposed in the first pump ring. The first pump ring and first liner partially define a first process volume. The second process chamber is in the chamber housing and includes a second pump ring and a second liner. The second pump ring includes a second port, a second baffle, and a second pressure conduit disposed in the second pump ring. The second pump ring and second liner partially define a second process volume. The pressure sensor is in fluid communication with the first process volume by the first pressure conduit, the chamber housing disposed at least partially between the pressure sensor and the first pressure conduit of the first pump ring. The foreline includes a first exhaust chamber fluidly coupled to the first process volume and a second exhaust chamber fluidly coupled to the second process volume.

In yet another embodiment, a processing system for semiconductor manufacturing is provided. The processing system includes a chamber housing, a first process chamber, a second process chamber, a pressure sensor, and a foreline disposed in the chamber housing and between the first process chamber and the second process chamber. The first process chamber is disposed in the chamber housing and includes a first pump ring and a first liner. The first pump ring is a metal pump ring and includes a first port, a first baffle, and a first pressure conduit disposed in the first pump ring. The first pump ring and first liner partially define a first process volume. The second process chamber is in the chamber housing and includes a second pump ring and a second liner. The second pump ring is a metal pump ring and includes a second port, a second baffle, and a second pressure conduit disposed in the second pump ring. The second pump ring and second liner partially define a second process volume. The pressure sensor is in fluid communication with the first process volume by the first pressure conduit, the chamber housing disposed at least partially between the pressure sensor and the first pressure conduit of the first pump ring. The foreline includes a first exhaust chamber fluidly coupled to the first process volume and a second exhaust chamber fluidly coupled to the second process volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 shows a top plan view of an exemplary processing system according to some embodiments.

FIG. 2 shows a schematic cross-sectional view of an exemplary plasma system according to some embodiments.

FIG. 3 shows a schematic cross-sectional view of an exemplary processing chamber according to some embodiments.

FIG. 4 shows a schematic cross-sectional view of an exemplary processing chamber according to some embodiments.

FIG. 5 shows a schematic cross-sectional view of an exemplary processing chamber according to some embodiments.

FIG. 6 shows an isometric view of an exemplary pump ring assembly according to some embodiments.

FIG. 7 shows an isometric view of an exemplary liner according to some embodiments.

FIG. 8 shows an isometric view of an exemplary pump ring according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

As device features reduce in size, tolerances across a substrate surface may be reduced, and material property differences across a film may affect device realization and uniformity.

Many chambers include a characteristic process signature, which may produce residual non-uniformity across a substrate. Temperature differences, flow pattern uniformity, and other aspects of processing may impact the films on the substrate, creating film uniformity differences across the substrate for materials produced or removed. For example, turbulent deposition gas flow and/or misalignment of apertures of a blocker plate and faceplate of a gas box may lead to non-uniform flow of deposition gases. In some instances, the blocker plate may not uniformly distribute flow of precursors to edge regions of a substrate. Additionally, in one embodiment which may be combined with other embodiments a substrate support or heater on which a substrate is disposed may include one or more heating mechanisms to heat a substrate. When heat is delivered or lost differently between regions of a substrate, the film deposition may be impacted where, for example, warmer portions of the substrate may be characterized by thicker deposition or different film properties relative to cooler portions. This temperature non-uniformity may be attributable, for example, to temperature fluctuations about the shaft of the pedestal and may particularly affect edge regions of substrates.

Further, separate chambers' performing similar processes on similar substrates potentially introduces unknown variables that can reduce throughput. In contrast, by increasing the number of substrates a system with uniform chambers can process, throughput is enhanced by the reduction of potentially introduced unknown variables.

The present technology overcomes these challenges by using processing chamber designs that provide symmetry within the processing environment. For example, the chambers described herein may provide symmetric gas flow, thermal distribution, and RF distribution, which may improve deposition characteristics. Additionally, the chamber designs may include processing regions that are isolated from the transfer region and cooler components, which may reduce the need for use of purge gases during processing operations and may therefore reduce dilution of process fluids, which may increase the material efficiency of the chamber. Additionally, the isolation of the processing region from the transfer region may enable a number of processing chambers within a single system to be operated independently of one another. Embodiments may also utilize non-motorized lift pins, which may enable a simplified design that eliminates the need for vertical motion of a transfer robot to handoff substrates with the substrate support. Accordingly, the present technology may produce improved film deposition characterized by improved thickness and material property uniformity across a surface of the substrate.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered as limited as for use with these specific deposition processes or chambers alone.

The disclosure discusses a possible system and chamber that may include lid stack components according to embodiments of the present technology before additional variations and adjustments to this system according to embodiments of the present technology are described.

The system increases throughput by reducing the size of the process volume in process chambers and a shared foreline enables about equal pressure in the process volumes that are supplied by the foreline. Further, the system is able to independently monitor the pressure in each process volume by pressure conduits that connect a process volume to a specific pressure sensor. Each process chamber also includes a baffle within a pump ring assembly. The baffle enhances deposition uniformity by distributing process fluids radially within the pump ring assembly before the process fluid passes through a liner and into a process volume.

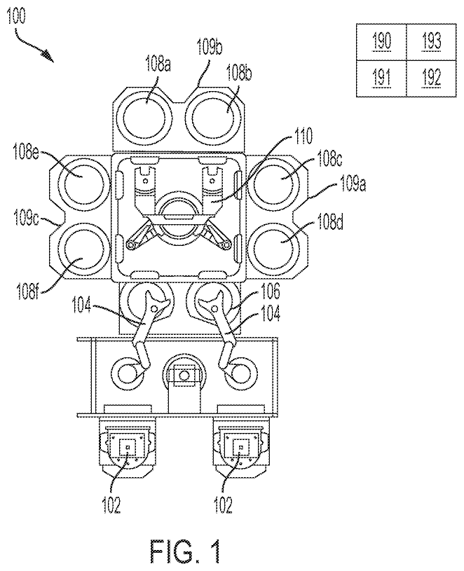

FIG. 1 shows a top plan view of one embodiment of a processing system 100 of process chambers according to embodiments. In the figure, a pair of front opening unified pods 102 supply substrates of a variety of sizes that are received by robotic arms 104 and placed into a low pressure holding area 106 before being placed into one of the substrate process chambers 108a-f, positioned in tandem sections 109a-c. A second robotic arm 110 may be used to transport the substrate wafers from the holding area 106 to the substrate process chambers 108a-f and back. Each substrate process chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate process chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by the processing system 100.

As shown, a controller 190 is in communication with the processing system 100 and is used to control processes and methods, such as the operations of the methods described herein. The controller 190 is configured to receive data or input as sensor readings from sensor(s) (such as one or more of sensor devices 281, 282 discussed below). The sensor devices can include, for example: sensor devices that monitor pressure in the processing chambers, e.g., 108a-b.

The controller 190 includes a central processing unit (CPU) 193 (e.g., a processor), a memory 191 containing instructions, and support circuits 192 for the CPU 193. The controller 190 controls various items directly, or via other computers and/or controllers. In one embodiment which can be combined with other embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like.

The controller 190 is configured to conduct any of the operations described herein. The instructions stored on the memory, when executed by the CPU 193, cause one or more of the operations described herein to be conducted in relation to the processing system 100. The controller 190 and the processing system 100 are at least part of a system for processing substrates.

The various operations described herein can be conducted automatically using the controller 190, or can be conducted automatically or manually with certain operations conducted by a user.

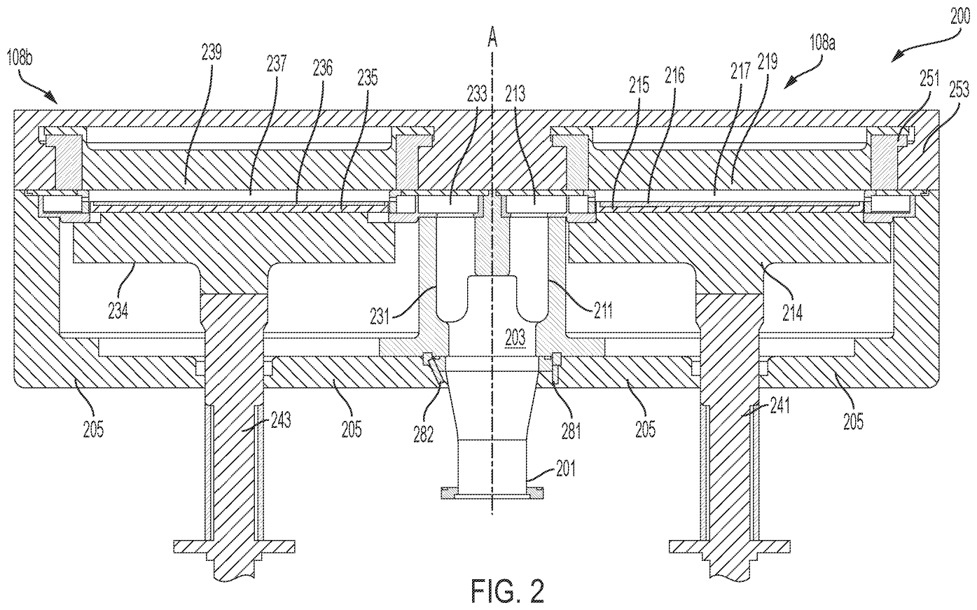

FIG. 2 shows a schematic cross-sectional view of an exemplary plasma system 200 according to one embodiment which may be combined with other embodiments.

The plasma system 200 is a tandem section 109(a-c) of FIG. 1. The plasma system 200 includes a foreline 201, the first process chamber 108a, and the second process chamber 108b.

The process chambers 108a, 108b are disposed in a chamber housing 205. In some embodiments that may be combined with other embodiments, the chamber housing 205 is a metallic monolithic chamber housing.

The first process chamber 108a includes a first process volume 217, a showerhead 219, a seal plate 214, a substrate support 215, a first pump ring assembly 213, a spacer 251, a lift column 241, and a lid 253. A substrate 216 is shown positioned on the substrate support 215.

The showerhead 219, the first pump ring assembly 213, and substrate support define the first process volume 217.

The first pump ring assembly 213 is in fluid communication with the foreline 201 by a first exhaust chamber 211.

The second process chamber 108b includes a second process volume 237, a showerhead 239, a seal plate 234, a substrate support 235, a second pump ring assembly 233, a spacer 251, a lift column 243, and a lid 253. In some embodiments, the lid 253 is a single piece. The spacer 251 is a ceramic. The lid 253 is a metal alloy, for example, an aluminum alloy. The spacer 251 separates the lid 253 from the showerheads 219, 239 of the first and second process chambers 108a, 108b. In some embodiments, each of the first and second process chambers 108a, 108b has its own spacer 251. A substrate 236 is shown positioned on the substrate support 235.

The showerhead 239, the second pump ring assembly 233, and the substrate support 235 define the second process volume 237.

The second pump ring assembly 233 is in fluid communication with the foreline 201 by a second exhaust chamber 231.

The foreline 201 includes a foreline chamber 203, the first exhaust chamber 211, and the second exhaust chamber 231. The exhaust chambers 211, 231 fluidly couple the first process volume 217 and the second process volume 237 to the foreline chamber 203 of the foreline 201. The first exhaust chamber 211 and the second exhaust chamber 231 are offset from a major vertical axis A of the foreline chamber 203.

The first exhaust chamber 211 is disposed between the foreline chamber 203 of the foreline 201 and the first process chamber 108a. The first exhaust chamber 211 separates the foreline 201 from the first process chamber 108a. The second exhaust chamber 231 is disposed between the foreline chamber 203 of the foreline 201 and the second process chamber 108b. The second exhaust chamber 231 separates the foreline 201 from the second process chamber 108b. The foreline 201, the exhaust chambers 211, 231, and the foreline chamber 203 are disposed in the housing 205 and between the process chambers 108a, 108b.

The first process volume 217 is separated from the second process volume 237 by the first exhaust chamber 211, the second exhaust chamber 231, and the foreline 201. The configuration of the foreline 201, the first exhaust chamber 211, and the second exhaust chamber 231, is configured to enable pressure equalization between the first process volume 217 and the second process volume 237.

The plasma system 200 is configured such that the first process volume 217 and the second process volume 237 are disposed in about the same plane. For example, the plane of the first process volume 217 and the second process volume 237 the foreline chamber 203 is disposed between the showerheads 219, 239 and the foreline chamber 203. In one embodiment which may be combined with other embodiments, the substrates 216, 236 are disposed above the foreline chamber 203 and the exhaust chambers 211, 231 during processing.

During processing, the pressure of the first process volume 217 and the second process volume 237 is between about 1 Torr to about 15 Torr, for example from about 2 Torr to about 10 Torr.

The lift columns 241, 243 translate the seal plates 214, 234. When the seal plates 214, 234 are disposed in a process position, as show in in FIG. 2, they form the process volumes 217, 237. When the seal plates 214, 234 are disposed in a transfer position (not shown) the first seal plate 214 is disposed away from the first pump ring assembly 213 and the second seal plate 234 is disposed away from the second pump ring assembly 233. This configuration enables a reduction in size of the process volumes 217, 237. In some embodiments, the lift columns 241, 243 may each include an internal port to supply a purge gas to their respective process volumes 217, 237.

The first process volume 217 and the second process volume 237 are reduced volumes, for example, less than 5 liters. In some embodiments, which may be combined with other embodiments, the process volumes 217, 237 are about 2 liters or less. For example, the process volumes 217, 237 are about 0.5 liters to about 5 liters. In the process volumes 217, 237 are about 2.5 liters to about 3.5 liters.

The shared foreline 201 and individual first exhaust chamber 211 and the second exhaust chamber 231 enable separate process volumes with about equal pressures without a dedicated equalization port between the first process volume 217 and the second process volume 237. By reducing the size of the process volumes 217, 237, the shared foreline 201 is able to exhaust process fluid and keep the pressures in first process volume 217 and the second process volume 237 at about equal.

The shared foreline 201 is configured to exhaust the process fluid from the first process volume 217 and the second process volume 237. The process fluid may include Tetraethyl Orthosilicate (TEOS) supplied at about 4,000 to about 6,000 milligrams per minute, oxygen at about 2,700 standard cubic centimeter per minute (sccm) to about 10,000 sccm, argon at about 3,200 sccm to about 8,000 sccm and any combination thereof. The process fluid may also include Silane, silane oxide, silane nitride, Ammonia

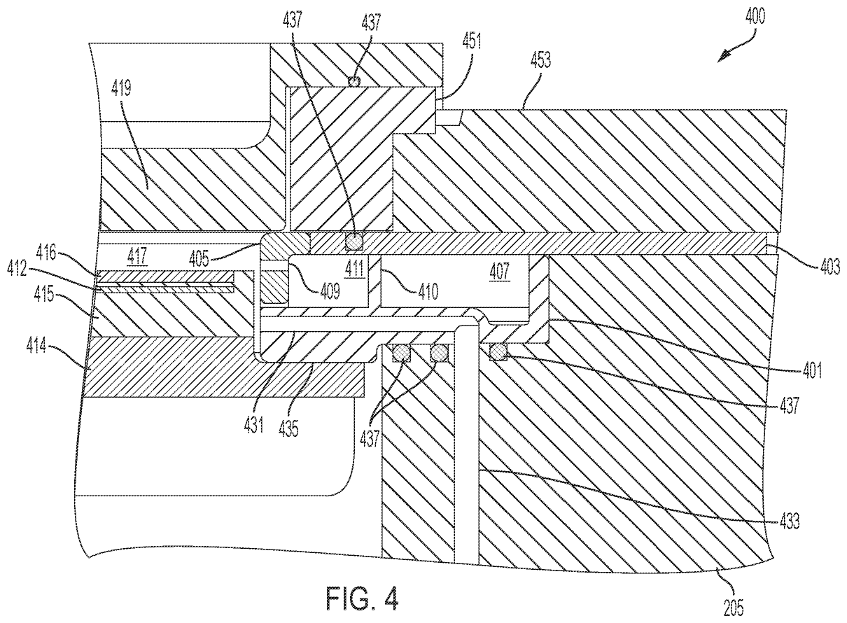

The plasma system 200 includes a first pressure sensor 281 and a second pressure sensor 282. The first pressure sensor 281 and the second pressure sensor 282 read the pressure in the first process volume 217 and the second process volume 237 of the first process chamber 108a, and the second process chamber 108b respectively. The first pressure sensor 281 and the second pressure sensor 282 are monometers according to some embodiments. The pressure sensors 281, 282 are in fluid communication with the corresponding process volumes through conduits in the pump ring assemblies 213, 233 and housing 205. The conduits are described in more detail with respect to FIG. 4.

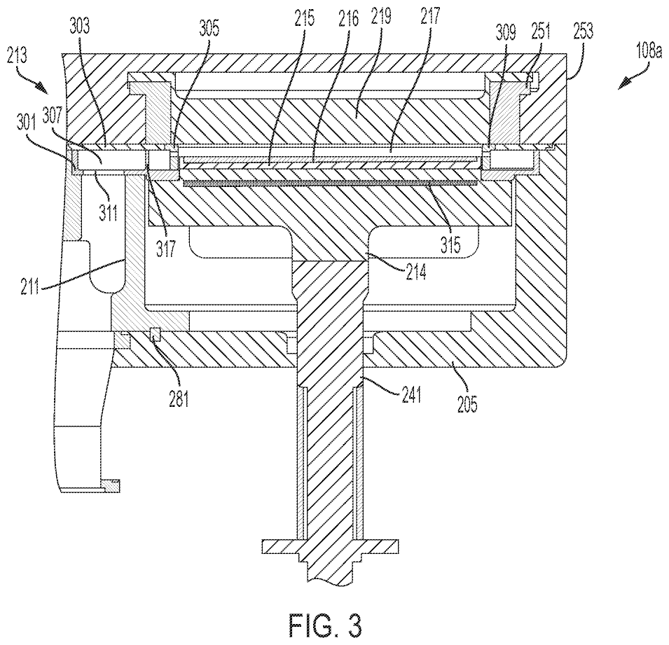

FIG. 3 shows a schematic cross-sectional view of an exemplary process chamber 108a according to one embodiment which may be combined with other embodiments. While the first process chamber 108a is shown, the second process chamber 108b may include the same or similar features. In one embodiment which may be combined with other embodiments, the first process chamber 108a is a mirror image of the second process chamber 108b.

The first pump ring assembly 213 includes a first liner 305, a first ring housing 303, and a first pump ring 301.

The first pump ring 301 is a metal pump ring according to one embodiment which may be combined with other embodiments. The first pump ring 301 and first liner 305 partially define the first process volume 217. The first process volume 217 may be further defined by the substrate support 215, the first liner 305, and the first showerhead 219. The first showerhead 219 is a ceramic according to one embodiment which may be combined with other embodiments.

The first pump ring 301 includes a first port 311 and a first baffle 317. The first pump ring 301, the first baffle 317 of the first pump ring 301, and the first ring housing 303 form a first port cavity 307.

The first port cavity 307 separates the first port 311 from the first ring housing 303 and the first baffle 317. The first port cavity 307 is fluidly coupled to the first exhaust chamber 211 by the first port 311.

According to one embodiment which may be combined with other embodiments, the first seal plate 214 includes a heater 315 disposed within the seal plate 214.

According to one embodiment which may be combined with other embodiments, the substrate support 215 includes the heater 315 disposed within the substrate support 215.

The first liner 305 includes one or more first exhaust apertures 309. The first exhaust apertures 309 are disposed radially through the first liner 305. The first exhaust apertures 309 fluidly couple the first port cavity 307 to the first process volume 217.

The first baffle 317 is disposed between the first port cavity 307 and the first exhaust apertures 309.

FIG. 4 shows a schematic cross-sectional view of an exemplary processing chamber 400 according to some embodiments. The processing chamber 400 may be the process chamber 108a or the process chamber 108b.

The processing chamber 400 includes the housing 205, a seal plate 414, a substrate support 415, a heater 412, a pump ring 401, a liner 405, a ring housing 403, a spacer 451, one or more seals 437, a lid 453, and a showerhead 419. A substrate 416 is shown positioned on the substrate support 415.

At least some of the one or more seals 437 are disposed between the housing 205 and the pump ring 401. At least one of the one or more seals 437 are disposed between the ring housing 403 and the lid 453. The seals 437 may also be disposed between the spacer 451 and the lid 453 and also may be disposed between the spacer 451 and the showerhead 419. The spacer 451 is disposed between the lid 453 and the showerhead 419.

In one embodiment which may be combined with other embodiments, the spacer 451 and liner 405 are made of ceramic materials and are configured to protect the metallic lid 453, ring housing 403, and pump ring 401 from RF signals produced during a process. The spacer 451 and liner 405 insulate the showerhead 419 from the grounded lid 453 and chamber housing 205.

The seal plate 414 has a sealing surface 435 that seals against the pump ring 401. The sealing surface 435 extends radially outward of the substrate support 415. The sealing surface 435 may include an elastomeric seal, a polymer seal, a radio frequency seal, or any combination thereof.

The sealing surface 435 of the seal plate 414 defines a lower bound of the process volume 417. For example, during processing, process fluid is disposed between the showerhead 419 and the sealing surface 435 to for a reduced process volume 417. The seal plate 414 is a metallic material and supports the substrate support 415. The substrate support 415 is a ceramic support disposed on the seal plate 414 away from the portion of the seal plate 414 from which the sealing surface 435 extends.

The pump ring 401 includes a pressure conduit 431 disposed in the pump ring 401. The pressure conduit 431 of the pump ring 401 is in fluid communication with a pressure conduit 433 of the housing 205. The pressure conduits 431, 433 connect to a pressure sensor. For example the pressure conduits 431, 433 fluidly couple a pressure sensor 282 (FIGS. 2, 3) to the process volume 417. For example, the pressure conduits 431, 433 connect the process volume 417 to the first pressure sensor 281 and/or the second pressure sensor 282 (FIG. 2). The pressure conduits 431, 433 have a diameter between about 3 millimeters and about 5 millimeters.

The pressure conduit 431 is disposed proximate the plane of the substrate 416 and process volume 417. The pressure conduit 431 is disposed between the sealing surface 435 of the seal plate 414 and the showerhead 419. For example, the pressure conduit 431 is disposed at about 10 millimeters to about 30 millimeters from the plane of the substrate 416 and process volume 417. The pressure conduits 431, 433 allow for the pressure sensor 282 (FIG. 3) to experience a pressure measurement adjacent and directly connected to the process volume 417. The proximity of the pressure conduit 431 allows for a reduction in potential sources of inaccuracy.

The liner 405, the pump ring 401, a baffle 410, and the ring housing 403 form an exhaust cavity 411. Process fluid leaves from the process volume 417 to the exhaust cavity 411 through one or more exhaust apertures 409 of the liner 405. For example, the liner 405 has about 100 to 200 exhaust apertures 409 in a radial array circumscribing the process volume 417 and through the liner 405. Process fluid from the process volume 417 applies pressure to a fluid in the pressure conduits 431, 433 which enables localized pressure measurement of the process volume 417 by the pressure sensor 282 (FIG. 3). The localized pressure measurement enhances measurement accuracy of the processing chamber 400.

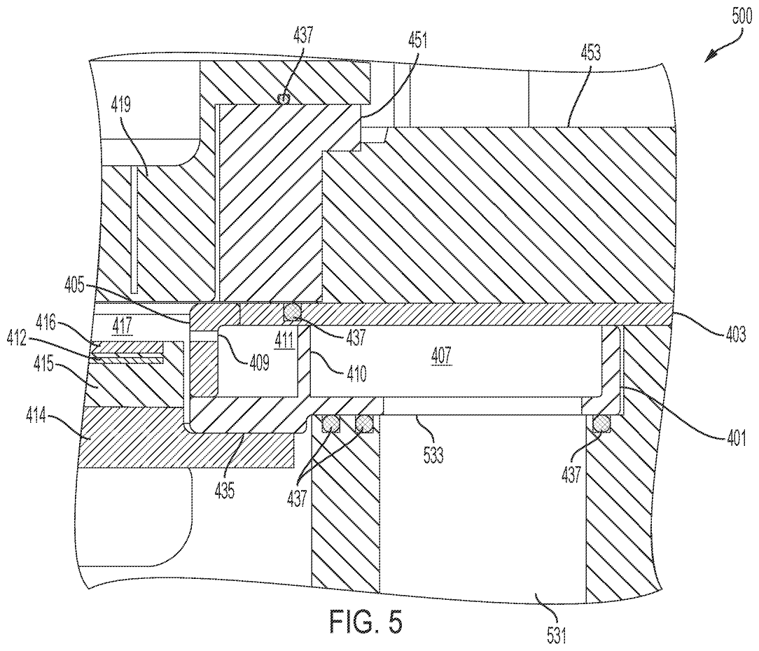

FIG. 5 shows a schematic cross-sectional view of an exemplary processing chamber 500 according to some embodiments. The processing chamber 500 may be the process chamber 108a, the process chamber 108b, or the processing chamber 400.

The processing chamber 500 includes a port cavity 407 in fluid communication with the foreline 201 by an exhaust chamber 531. The exhaust chamber 531 is in fluid communication with the port cavity 407 by a port 533. Process fluid passes from the port cavity 407 to the foreline chamber 203 of the foreline 201, through the port 533.

The port cavity 407 is defined by the baffle 410, the pump ring 401, the ring housing 403 and the port 533. Process fluid flows from the exhaust cavity 411 around the baffle 410 and between the pump ring 401 and the ring housing 403 to enter the port cavity 407. Process fluid flows out of the port cavity 407 through the port 533 to the exhaust chamber 531. Process fluid leaves the process volume 417 to the exhaust cavity 411 through the exhaust apertures 409.

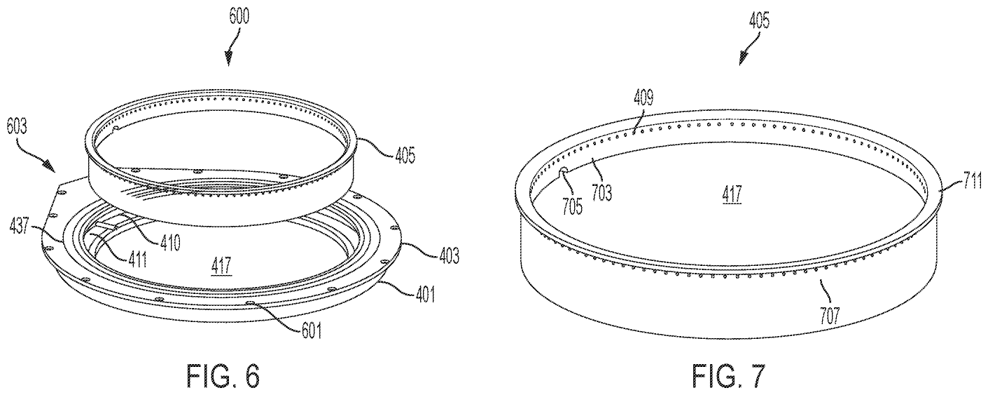

FIG. 6 shows an isometric view of an exemplary pump ring assembly 600 according to some embodiments. The pump ring assembly 600 may be the pump ring assembly 213 or pump ring assembly 233 of FIGS. 2 and 3.

The pump ring assembly 600 includes the ring housing 403, the pump ring 401, and the liner 405. The liner 405 is illustrated away from the ring housing 403 for illustrative purposes. The liner 405 is disposed radially inward of the ring housing 403.

When the liner 405 is placed within the pump ring assembly 600, the pump ring 401, the ring housing 403, and the liner 405 form the exhaust cavity 411.

The ring housing 403 includes mounting holes 601, a tongue 603, and seals 437. The mounting holes 601 are disposed in a radial array around the process volume 417. The mounting holes 601 are configured to allow the pump ring assembly 600 to be coupled to the housing 205 (FIG. 2).

The tongue 603 is the portion of the ring housing 403 that is disposed over the port 533 and partially defines the port cavity 407 (FIG. 5). In one embodiment which may be combined with other embodiments the tongue 603 is a trapezoidal feature of the ring housing 403.

FIG. 7 shows an isometric view of an exemplary liner 405 according to some embodiments.

The liner 405 includes an inner surface 703, the exhaust apertures 409, a cavity surface 707, an extension 711, and an index feature 705.

The extension 711 is a portion of the liner 405 that extends from the inner surface 703 radially outward past the cavity surface 707.

The index feature 705 is a semicircular notch in the liner 405 that is configured to align with pressure conduit 431. The pressure conduit 431 has geometry that is discussed below.

The index feature 705 and the exhaust apertures 409 are disposed from the inner surface 703 radially outward past the cavity surface 707. The exhaust apertures 409 are disposed between the index feature 705 and the extension 711. The outer radial face of the extension 711 is disposed in contact and seals with an inner radial face of the ring housing 403 (FIG. 6).

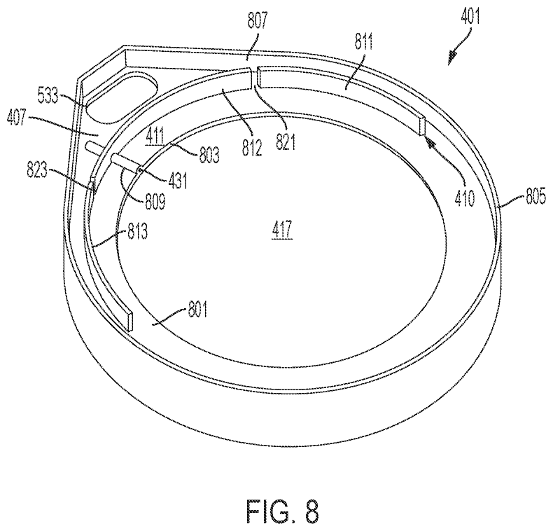

FIG. 8 shows an isometric view of an exemplary pump ring 401 according to some embodiments.

The pump ring 401 includes an inner surface 801, an inner radial surface 803, a top surface 805, a conduit feature 809, and a wall 807.

The inner surface 801 is about perpendicular to the inner radial surface 803. The port 533 is an aperture through the inner surface 801. The inner radial surface 803 circumscribes and faces the process volume 417.

The wall 807 is the outer most body of the pump ring 401. In one embodiment which may be combined with other embodiments the wall 807 and the baffle 410 extend from the inner surface 801 at an about equal length. For example, the baffle 410 extends from the inner surface 801 from about 1 inch to about 1.5 inches, for example about 1.2 inches.

The baffle 410 extends from the inner surface 801 to about parallel with the top surface 805. The top surface 805 and the baffle 410 seal against the ring housing 403 (FIG. 6). The port cavity 407 is partially defined by the wall 807, the inner surface 801, and a second section 812 of the baffle 410. The baffle 410 partially circumscribes the process volume 417.

The baffle 410 includes one or more sections separated by slits. In one embodiment which may be combined with other embodiments, the baffle 410 includes a first section 811, the second section 812, and a third section 813. The first and second sections 811, 812 are separated by a first slit 821. The second and third sections 812, 813 are separated by a second slit 823. In one embodiment which may be combined with other embodiments the first section 811, the second section 812, and the third section 813 are about equal. In one embodiment which may be combined with other embodiments the first section 811 and the third section 813 are larger than the second section 812. For example, an arc length of the first section 811 and the third section 813 is about 10% or more than the arc length of the second section 812.

In one embodiment which may be combined with other embodiments the first section 811 and the third section 813 are smaller than the second section 812. For example, an arc length of the second section 812 is about 10% or more than the arc lengths of the first section 811 and the third section 813.

The first slit 821 is the gap between the first and second sections 811, 812. The second slit 823 is the gap between the second and third sections 812, 813. The first slit 821 and the second slit 823 are sized based on the process fluid used. For example, the first slit 821 and the second slit 823 are between about 2 millimeters and about 4 millimeters.

In one embodiment which may be combined with other embodiments the baffle 410 is disposed radially around about half or more of the process volume 417. For example, the baffle 410 is disposed circumferentially around 40% to about 60% of the process volume 417. In one embodiment which may be combined with other embodiments the baffle 410 is disposed in adjacent segments around a portion of the process volume 417. The baffle 410 is disposed at an offset from the inner radial surface 803 to partially form the exhaust cavity 411.

The conduit feature 809 is a raised portion of the inner surface 801 of the pump ring 401. The conduit feature 809 is concentric with the pressure conduit 431. The conduit feature 809 extends through the baffle 410. The conduit feature 809 is disposed between the first slit 821 and the second slit 823. The conduit feature 809 extends from the process volume 417, through the baffle 410, to the port cavity 407. The conduit feature 809 allows the pressure conduit 431 to be disposed closer to the process volume 417 from the sealing surface 435 of the seal plate 414 (FIG. 4). Disposing the pressure conduit 431 closer to the process volume 417 allows the pressure conduit 431 to experience the pressure of the process volume 417 with enhanced accuracy. The pressure conduit 431 is an aperture through the inner radial surface 803 that allows the pressure sensor 282 (FIG. 3) to experience the process volume 417.

The conduit feature 809 indexes with the index feature 705 which allows the pressure conduit 431 to be disposed elevated in relation to the inner surface 801 such that the pressure conduit 431 is closer to the top surface 805

The exhaust cavity 411 is defined by the baffle 410, the portion of the wall 807 across the process volume 417 from the baffle 410, and the portion of the inner surface 801 radially inward of the baffle 410.

As process fluid travels from the port 533, the process fluid leaves the port cavity 407. Process fluid enters the exhaust cavity 411 through the exhaust apertures 409. Process fluid travels through the slits 821, 823 and around the distal edges of the first and third sections 811, 813, as it leaves the exhaust cavity 411 and enters the port cavity 407. The baffle 410 allows for enhanced flow by equalizing the flow rate of process fluid through exhaust apertures 409.

During a process the flow of process fluid is in the incompressible flow regime. For example, the first slit 821 and the second slit 823 allow for flow of process fluid in the viscous flow regime and enhance deposition uniformity during a process.

The slits 821, 823 of the baffle 410 represent about 10% or less of the baffle 410. For example, in embodiments where the baffle 410 does not have a slit, the baffle is at 100%. In some embodiments that may be combined with other embodiments, the slits 821, 823 allow process fluid to pass through 10% or less of the baffle.

The baffle 410 and slits 821, 823 enhance azimuthal flow of process fluid in the process volume 417 by exhausting the process fluid through the exhaust apertures 409 of the liner 405. The azimuthal flow of process fluid in the process volume 417 enhances deposition uniformity on a substrate.

Benefits of the present disclosure include reduced gas consumption and gas waste; increased chamber condition measurement accuracy; and more uniform deposition. Benefits also include enhanced manufacturability, reduced divertive gas flow, and reduction of processing volume size.

It is contemplated that one or more aspects disclosed herein may be combined. As an example, one or more aspects, features, components, operations and/or properties of the process chambers 108a, 108b; the controller 190; the one or more sensor devices 281, 282; the baffle 410; the foreline 201; the pressure conduit 431, 433; and/or the exhaust chambers 211, 231 may be combined to enhance measurement accuracy, through put, and or deposition uniformity.

While the foregoing is directed to embodiments of the present disclosure, other and further embodiments of the disclosure may be devised without departing from the basic scope thereof, and the scope thereof is determined by the claims that follow

What is claimed is:

1. A processing system for semiconductor manufacturing, the processing system comprising:
a chamber housing;
a first process chamber disposed in the chamber housing, the first process chamber comprising:
a first liner; and
a first pump ring, the first pump ring comprising:
a first port; and
a first baffle, the first pump ring and first liner partially defining a first process volume;
a second process chamber disposed in the chamber housing, the second process chamber comprising:
a second liner; and
a second pump ring, the second pump ring comprising:
a second port; and
a second baffle, the second pump ring and second liner partially
defining a second process volume; and
a foreline disposed in the chamber housing and between the first process chamber and the second process chamber, the foreline comprising:
a first exhaust chamber fluidly coupled to the first process volume; and
a second exhaust chamber fluidly coupled to the second process volume.

2. The processing system of claim 1, wherein the first liner, the first baffle, and the first pump ring partially define an exhaust cavity.

3. The processing system of claim 2, wherein the first liner comprises an exhaust aperture, the first baffle disposed between the first port and the exhaust aperture.

4. The processing system of claim 1, wherein the first baffle is disposed radially around half or less of the first process volume.

5. The processing system of claim 1, wherein the first baffle comprises one or more slits disposed between and fluidly connecting the first process volume and the first port, the one or more slits forming one or more sections of the first baffle.

6. The processing system of claim 5, wherein the one or more sections of the first baffle are about equal.

7. The processing system of claim 1, further comprising:
a lid; and
a first ring assembly, the first ring assembly defining an exhaust cavity, the first ring assembly comprising:
the first liner;
a first ring housing disposed radially outward of the first liner; and
the first pump ring, the distribution ring and the first ring housing disposed between the lid and the first pump ring.

8. The processing system of claim 1, wherein foreline further comprises a foreline chamber disposed between the first exhaust chamber and the second exhaust chamber, the first process volume being separated from the second process volume by the first exhaust chamber, the foreline chamber, and the second exhaust chamber.

9. The processing system of claim 1, wherein the first baffle is disposed between the first port and the first process volume.

10. A processing system for semiconductor manufacturing, the processing system comprising:
a chamber housing;
a first process chamber disposed in the chamber housing, the first process chamber comprising:
a first liner; and
a first pump ring, the first pump ring comprising:
a first port;
a first baffle, the first pump ring and first liner partially defining a first process volume; and
a first pressure conduit disposed in the first pump ring;
a second process chamber disposed in the chamber housing, the second process chamber comprising:
a second liner; and
a second pump ring, the second pump ring comprising:
a second port;
a second baffle, the second pump ring and second liner partially defining a second process volume; and
a second pressure conduit disposed in the second pump ring;
a foreline disposed in the chamber housing and between the first process chamber and the second process chamber, the foreline comprising:
a first exhaust chamber fluidly coupled to the first process volume; and
a second exhaust chamber fluidly coupled to the second process volume; and
a pressure sensor in fluid communication with the first process volume by the first pressure conduit, the chamber housing disposed at least partially between the pressure sensor and the first pressure conduit of the first pump ring.

11. The processing system of claim 10, wherein the first pressure conduit passes through the first baffle.

12. The processing system of claim 10, wherein the first liner comprises an index feature configured to enable the first pressure conduit to experience a pressure in the first process volume.

13. The processing system of claim 10, wherein the first process chamber further comprises a ring housing, the ring housing disposed radially outward of the first liner.

14. The processing system of claim 13, wherein the ring housing, the first baffle, and the first pump ring partially define a port cavity.

15. The processing system of claim 14, wherein the first liner, the first baffle, and the first pump ring partially define an exhaust cavity, the first baffle disposed between the exhaust cavity and the port cavity.

16. The processing system of claim 10, wherein the chamber housing comprises a pressure conduit disposed between the pressure sensor and the first pressure conduit.

17. The processing system of claim 10, wherein the first baffle comprises one or more slits disposed between and fluidly connecting the first process volume and the first port, the one or more slits forming one or more sections of the first baffle.

18. The processing system of claim 10, wherein the first process volume is separated from the second process volume by the first exhaust chamber, the second exhaust chamber, and the foreline, the first baffle and second baffle, the first exhaust chamber, the second exhaust chamber, and the foreline configured to enable pressure equalization between the first process volume and the second process volume.

19. A processing system for semiconductor manufacturing, the processing system comprising:
a chamber housing;
a first process chamber disposed in the chamber housing, the first process chamber comprising:
a first liner; and
a first pump ring, the first pump ring being a metal pump ring, the first pump ring comprising:
a first port;
a first baffle, the first pump ring and first liner partially defining a first process volume, the first process volume being less than about 5 liters; and
a first pressure conduit disposed in the first pump ring;
a second process chamber disposed in the chamber housing, the second process chamber comprising:
a second liner; and
a second pump ring, the second pump ring being a metal pump ring, the second pump ring comprising:
a second port;
a second baffle, the second pump ring and second liner partially defining a second process volume, the first process volume about equal to the second process volume; and
a second pressure conduit disposed in the second pump ring;
a foreline disposed in the chamber housing and between the first process chamber and the second process chamber, the foreline comprising:
a first exhaust chamber fluidly coupled to the first process volume; and
a second exhaust chamber fluidly coupled to the second process volume; and
a pressure sensor in fluid communication with the first process volume by the first pressure conduit, the chamber housing disposed at least partially between the pressure sensor and the first pressure conduit of the first pump ring.

20. The processing system of claim 19, wherein the first process volume and the second process volume are in about a same plane.
